(19) United States
(12) Patent Application Publication
(10) Pub. No.: US 2005/0224914 A1
(43) Pub. Date: Oct. 13, 2005

(54) Semiconductor integrated circuit device, method of enerating pattern thereof, method of manufacturing the same, and pattern generating apparatus for the same

(75) Inventors: Kiyohito Mukai, Kyoto (JP); Hiroyuki Tsujikawa, Shiga (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/103,490

(22) Filed: Apr. 12, 2005

(30) Foreign Application Priority Data
Apr. 12, 2004 (JP) P. 2004-117118

(51) Int. Cl. H01L 31/0392

(52) U.S. Cl. 257/532

(57) ABSTRACT

To provide a semiconductor integrated circuit device capable of effectively absorbing power supply noise, of achieving the stable operation of a circuit, and particularly, of absorbing noise in a vicinity of a noise generating source.

The semiconductor integrated circuit device has at least one circuit block. The semiconductor integrated circuit device includes a bypass capacitor having a first conductor layer 1a formed on the circuit block and a second conductor layer 1b formed on the first conductor layer 1a with a capacitor insulating film 1c interposed therebetween. One of the first and second conductor layers of the bypass capacitor is connected to one of a grounding wiring line or a power supply wiring lines through a substrate contact which fixes a potential of a substrate and the other is connected to the other of the power supply wiring line or the grounding wiring line.

### BACKGROUND OF THE INVENTION

1. Field of the Invention

The present invention relates to a semiconductor integrated circuit device, a method of generating a pattern of the semiconductor integrated circuit device, a method of manufacturing the semiconductor integrated circuit device, and a pattern generating apparatus for the semiconductor integrated circuit device. More particularly, the invention relates to a semiconductor integrated circuit device including a bypass capacitor and an inductor to protect the semiconductor integrated circuit device against a noise and a method of generating a pattern of the semiconductor integrated circuit device.

2. Description of the Related Art

LSIs have been widely used in communication apparatuses such as cellular phones, general home appliances or toys, and automobiles as well as computers. However, electromagnetic interference (EMI) occurred in these apparatuses causes radio interference to be generated at receiving devices such as a television and a radio or causes malfunction to be generated at another system. To overcome these problems, counter measures for the entire apparatus, such as a filtering or a shielding, have been performed. However, according to this method, there is a problem in that the number of components increases to raise costs. Alternatively, the noise suppression in an LSI package has been strongly requested.

Under these circumstances, in each apparatus, the LSI serves as a key device and is provided at a proper location. In order to ensure competitive goods, an LSI having a large size and a high speed has been requested. Under the circumstances that a product life cycle becomes short, in order to cope with these requests, it is necessary to automate design of the LSI. As prerequisites for introducing a design automation technology, it is necessary to adopt a synchronization design. However, when all circuits are operated in synchronization with a reference clock and the LSI has a large size and a high speed, an instantaneous current extremely increases, so that the electromagnetic interference increases.

As such, as the size of the LSI is minute and the speed of an operation frequency is high, it has been an important issue to remove the noise.

Generally, in a cell-based design method, capacitor cells are arranged at a periphery of a cell which is easy to be influenced upon a changing of a power supply voltage, and terminals located at both electrodes of the capacitor are fixed to a power supply wiring line and a grounding wiring line, thereby forming a bypass capacitor. As a result, it is possible to suppress the power supply voltage from being changed and to suppress the noise from being transmitted through the power supply.

However, as a measure for latch-up, when the capacitor cells are additionally provided in the vicinity of the substrate cell, the chip area increases.

Therefore, an applicant proposes a method in which by preventing the chip area from being increased, detecting an unused region after layout of the pattern, arranging a substrate contact under the power supply wiring line of the unused region, and arranging the capacitor having a bypassed cell between the power supply wiring line and the grounding wiring line, it is possible to suppress the area of the semiconductor integrated circuit device from being increased, to suppress the noise from being transmitted, and to suppress the malfunction from occurring due to the noise infiltrated from the exterior (see Japanese Patent Application No. 2002-229216).

According to this method, it is possible to suppress the malfunction from occurring due to the noise without increasing the area of the semiconductor integrated circuit.

On the other hand, when a CMOS logic circuit is switched, the power supply current flows. When the power supply current passes through an inductor of a bonding wire of a package, the power supply noise is generated. The power supply noise is often generated in a digital circuit and has a bad influence on other apparatuses by the electromagnetic interference (EMI). In addition, at an LSI in which analog/digital (A/D) circuits are mixed, the noise generated at a digital circuit is transmitted to an analog circuit through the substrate to have a bad effect on the performance of the analog circuit.

For this reason, even though a bypass capacitor having a necessary capacitance is arranged in an unused region after layout of the pattern, a location at which the bypass capacitor is arranged is between a circuit block and another circuit block, so that the bypass capacitor is far from a noise source in the circuit block. Therefore, there is a problem in that a noise reduction effect is insufficient.

Further, since the bypass capacitor of the related art occupies the surface of the substrate, the occupying area on the circuit block increases when the bypass capacitor is arranged adjacent to the circuit block.

Furthermore, even though the bypass capacitor is provided on the surface of the semiconductor substrate having the multi-layered wiring structure, since there are many cases in which the power supply wiring line is provided on an upper layer, a distance in a vertical direction is large and an increase of a parasitic resistance due to the distance of the wiring line in the vertical direction becomes a problem.

### SUMMARY OF THE INVENTION

The present invention is designed to solve the above-mentioned problems, and it is an object of the invention to provide a semiconductor integrated circuit device capable of absorbing power supply noise effectively and of performing the stable operation of a circuit. Specifically, it is the object of the invention to provide a semiconductor integrated circuit device capable of absorbing noise in a vicinity of a noise generating source.

Further, it is another object of the invention to provide a semiconductor integrated circuit device capable of reducing power supply noise reliably and of automating pattern generation with ease.

Furthermore, it is still another object of the invention to provide a semiconductor integrated circuit device capable of reducing power supply noise reliably and of forming a capacitor having a large capacitance without increasing an occupation area.

In order to achieve the above-mentioned objects, in a semiconductor integrated circuit device of the invention, a bypass capacitor is not arranged on an unused region after layout design, but is formed on an upper layer portion of a necessary circuit block. Thereby, it is possible to achieve a noise reduction effect through the reduction of a chip area and the optimal arrangement of the bypass capacitor.

That is, according to a first aspect of the invention, there is provided a semiconductor integrated circuit device having at least one circuit block including: a bypass capacitor having a first wiring layer and a second wiring layer formed on the first wiring layer with a capacitor insulating film interposed therebetween, wherein the first and second wiring layers are formed to be respectively connected to two power supply lines which are connected to the circuit block and which have differential potentials.

According to this aspect, since the bypass capacitor is formed adjacent to the wiring layer such that it is connected to the circuit block where the capacitor is to be formed, it is possible to reduce a parasitic resistance.

In the MOS-type bypass capacitor of the related art, it is necessary that the bypass capacitor be formed on the surface of the substrate. In addition, since the bypass capacitor should be provided at a periphery of the circuit block without forming the bypass capacitor on the center portion of the circuit block, an actual occupation area increases.

Also, in the MOS-type bypass capacitor, since the bypass capacitor is formed on the surface of the substrate, the length of the wiring line increases in a vertical direction when being connected to the power supply wiring line of the upper layer portion. On the contrary, in a multi-layered structure, the distance of the wiring line decreases in the vertical direction. Also, since the vertical direction is actually adjacent to a horizontal direction, the parasitic resistance is reduced.

Further, in the semiconductor integrated circuit of the invention, the bypass capacitor is arranged on the circuit block.

According to this aspect, since the bypass capacitor is arranged on the circuit block in which the capacitor is to be formed, it is possible to considerably reduce the distance of the wiring line in the vertical direction and to reduce the parasitic capacitance. Also, the capacitor insulating film is formed on the wiring pattern of the circuit block, serving as the noise source, without forming the bypass capacitor under the unused region, and thus the capacitor is formed. Therefore, it is possible to form the capacitor with the simple configuration without increasing the chip area. Moreover, since the capacitor can be provided at the location adjacent to the noise source, it is possible to reduce the noise reliably.

Furthermore, in the semiconductor integrated circuit device of the invention, one of the first and second wiring layers of the bypass capacitor is connected to a grounding wiring line through a substrate contact which fixes a potential of a substrate and the other is connected to the power supply wiring line.

According to this aspect, by connecting the bypass capacitor to the adjacent grounding wiring line and the adjacent power supply wiring line through the substrate contact, it is possible to form the bypass capacitor and to form the pattern having high reliability with the simple configuration.

Moreover, in the semiconductor integrated circuit device of the invention, the bypass capacitor is formed with a capacitor insulating film interposed between the first and second conductor layers constituting one wiring layer, in other region of the semiconductor integrated circuit.

According to this aspect, the wiring layer is formed in a two-layer structure, and the dielectric layer is provided in a region in which the capacitive element is to be formed. As a result, it is possible to additionally provide the capacitor with ease. That is, the entire region of the first and second conductor layers, which are opposite to each other, serves as the capacitor, and accordingly the area can be effectively used. In addition, since the substrate side potential can be also extracted through the diffusion region, the size of a resistor for the potential extraction can be decreased, and thus it can be integrally formed over the large area. Also, since the first and second conductor layers can be formed with the same process as that of the wiring layer, the manufacturing of the first and second conductor layers can be easily performed. Also, the first and second conductor layers may be formed of different materials. In addition, the first and second conductor layers may be formed of the same material and the dielectric layer becoming the capacitor insulating film may be interposed therebetween during a manufacturing process.

In the semiconductor integrated circuit device of the invention, one of the power supply lines is a grounding wiring line and the other is a power supply wiring line.

According to this aspect, it is possible to reliably form the capacitor between the power supply wiring line and the grounding wiring line.

In the semiconductor integrated circuit device of the invention, the first wiring line is connected to the grounding wiring line or power supply wiring line through a diffusion region formed on a surface of the substrate.

According to this aspect, since the bypass capacitor is formed between the power supply wiring line and the grounding wiring line of which potentials are fixed to the substrate potential only by additionally forming the contact, it is possible to form the bypass capacitor without increasing the occupation area.

In the semiconductor integrated circuit device of the invention, the bypass capacitor is composed of a plurality of unit cells, and the plurality of unit cells are arranged on the circuit block in a matrix or array.

According to this aspect, the plurality of unit cells is arranged, so that the operation is easy. In addition, it is possible to easily form the pattern at high speed.

In the semiconductor integrated circuit device of the invention, the first wiring layer contacts with a first diffusion region formed on the surface of the substrate, and the first diffusion region is connected to a second diffusion region serving as a substrate contact which fixes the potential of the substrate.

According to this aspect, the first diffusion region can be efficiently connected to the second diffusion region without additionally providing the contact region.

In the semiconductor integrated circuit device of the invention, the first diffusion region has the same conductive type as that of the second diffusion region constituting the substrate contact.

According to this aspect, the first diffusion region can be easily connected to the second diffusion region and a connection resistance can be reduced.

In the semiconductor integrated circuit device of the invention, the first diffusion region has a different conductive type from that of the second diffusion region constituting the substrate contact, and the first and second diffusion regions are connected to each other through a silicide layer formed on a surface of the second diffusion region constituting the substrate contact.

According to this aspect, at a portion connected with the substrate contact, if it is connected in the diffusion layer, since it has a reverse conductive type, a region having the small number of carriers is formed at the interface, so that the connection resistance increases. However, the silicide process is performed, so that the diffusion region under the gate electrode is connected through the silicide layer provided on the surface of the diffusion region. Therefore, the connection resistance can be reduced, and thus the superior bypass capacitor can be obtained.

Actually, when the pattern is generated, the region where the decoupling capacitor can be arranged is selected. When the connecting diffusion layer is arranged, a part where the substrate contact region and the connecting diffusion region overlap is separated to be connected to the wiring line. The processes can be automatically performed through a graphical logic operation and a resizing process.

In addition, in the semiconductor integrated circuit device of the invention, the bypass capacitor is formed on the circuit block with the interlayer insulating film interposed therebetween and is composed of a first wiring layer having uneven portions formed on the surface thereof and a second wiring layer formed by interposing a capacitor insulating film therebetween.

According to this aspect, it is possible to increase the capacitance only by changing the wiring pattern. In addition, by not only forming the uneven portions but also suitably adjusting a shape of the capacitor in a fin shape, it is possible to achieve a capacitor having a large capacitance.

In the semiconductor integrated circuit device of the invention, the bypass capacitor is formed by sequentially laminating a first wiring layer formed along an inner wall of a trench formed on a surface of an insulating film and a capacitor insulating film and a second wiring layer formed on the first wiring layer.

According to this aspect, it is possible to increase a capacitance per unit area and to obtain a bypass capacitor having a large capacitance without increasing an occupation area.

In the semiconductor integrated circuit device of the invention, the trench is formed along a trench separating region.

In this way, by forming the first wiring layer such that it surpasses the trench separating region to have a step difference, it is possible to form a bypass capacitor having a large capacitance.

Preferably, the bypass capacitor is formed with a minimum graphic size of the wiring pattern rule in manufacturing the semiconductor.

According to this aspect, it is possible to design the pattern automatically.

Preferably, the bypass capacitor has a different capacitor insulating film, and a capacitance per unit area in the chip is different.

Here, the situation of the region is determined from the design rule in consideration of specification, and the bypass capacitor having the different characteristics is provided for each region. Generally, it is necessary that a high withstand voltage exist at an outer circumference of the chip located near the power supply in order to prevent the surge. On the contrary, it is not necessary that a high withstand voltage exist at the inside of the chip. For this reason, a thickness of the gate insulating film is large in the vicinity of the outer circumference of the chip and the thickness of the gate insulating film is small at the inside of the chip. In addition, there is a case in which the gate insulating film having the multi-layered structure is provided only in the vicinity of the outer circumference of the chip. Therefore, when the capacitor cells are formed simultaneously with the peripheral circuit element, the thickness of the capacitor insulting film may be selected according to the peripheral circuit element. In addition, it may be controlled by the necessary capacitance or withstand voltage.

In addition, the frequency characteristics are important in the vicinities of the functional elements. That is, it is necessary that the bypass capacitor having a large capacitance be provided for use in a high frequency, while the bypass capacitor having a small capacitance be provided for use in a low frequency.

Here, the distance from the chip frame toward an inner direction may be divided into a peripheral portion and the inner portion by the logic operation and resizing process with the process information set an original distance, and thus the bypass capacitors having different specifications may be arranged. The situation of the region is determined from the design rule in consideration of the specification, and the bypass capacitor having the different characteristics is provided for each region. As a result, it is possible to provide a semiconductor integrated circuit device with excellent characteristics and high reliability.

According to a second aspect of the invention, there is provided a method of generating a pattern of a semiconductor integrated circuit device, comprising: a step of forming a layout pattern to design and arrange the layout pattern of a semiconductor chip; a step of selecting a circuit block, in which a noise is easy to be generated, from the layout pattern; a step of determining whether capacitor cells can be arranged on the circuit block; and a step of arranging a capacitor using, as an arrangement region, a region determined that the capacitor cells can be arranged on the circuit block in the determination step.

In the method of the second aspect, since the circuit block, in which a noise is easy to be generated, is selected, and the bypass capacitor is arranged on the circuit block, it is possible to automatically form a pattern layout and further to easily and effectively perform the pattern layout.

According to the second aspect of the invention, the determination step includes a step of detecting a wiring layer region, in which the capacitor cells are formed, in the circuit block of the layout pattern and of determining whether the capacitor cells can be arranged on the wiring layer region, and the capacitor arrangement step includes a wring line arrangement step of arranging a second wiring layer such that the capacitor insulating film is interposed in an upper layer or a lower layer of the wiring layer region determined that the capacitor cells can be arranged on the wiring layer region in the determination step and of wiring the second wiring layer such that the second wiring layer is connected to a different potential from that of the wiring layer region.

According to this aspect, the wiring layer region in which the capacitor cells are formed on the circuit block is detected and it is determined whether the capacitor cells can be arranged. Therefore, the capacitor cells can be easily arranged on the circuit block which becomes the noise generating source.

In addition, according to this aspect, the wiring line arrangement step includes a step of connecting the second wiring layer to a power supply wiring line or a grounding wiring line.

As such, only by connecting the second wiring layer to the power supply layer or the grounding layer, it is possible to form the capacitor with ease.

Moreover, in the method of the invention, the determination step includes: a step of detecting a region, in which capacitor cells are formed, in the circuit block among wiring lines of the layout pattern; a step of arranging the capacitor cells in a region determined that the capacitor cells can be formed in the determination step; and a step of arranging wiring lines such that one conductor of each of the capacitor cells is connected to a first potential and a substrate is connected to a second potential.

According to this aspect, it is possible to form a semiconductor integrated circuit device automatically.

Further, according to a third aspect of the invention, there is provided a pattern generating apparatus for semiconductor integrated circuit device including: a layout pattern forming means for designing and arranging a layout pattern of a semiconductor chip; an selection means for selecting a circuit block, in which a noise is easy to be generated, from the layout pattern; a determination means for determining whether capacitor cells can be arranged on the circuit block; and a capacitor arrangement means for arranging a capacitor using, as an arrangement region, a region determined that the capacitor cells can be arranged on the circuit block in the determination means.

Furthermore, according to a fourth aspect of the invention, there is provided a method of manufacturing a semiconductor integrated circuit device using the pattern for the semiconductor integrated circuit device generated by the method of generating the pattern of the semiconductor integrated circuit device mentioned above.

Since the semiconductor integrated circuit device of the invention is formed on the circuit block, in which the noise is easy to be generated, rather than the unused region, by forming the bypass capacitor using the wiring layer, it is possible to form the bypass capacitor without increasing the chip area and the number of processes. In this way, the noise can be reduced. Also, when the pattern is generated, it is automatically searched using the graphical logic operation and the resizing process such that the circuit block, in which the noise is easy to be generated, is selected and it is determined whether the decoupling capacitor can be generated, and the searched area is used as the decoupling capacitor wiring region. Therefore, it is possible to generate the pattern automatically and to reduce the noise with high precision.

Further, according to the pattern generating apparatus for semiconductor integrated circuit device, the power supply noise can be effectively absorbed. Also, it is possible to automatically form the layout pattern of the semiconductor integrated circuit device in which the circuit can be stably operated.

### BRIEF DESCRIPTION OF THE DRAWINGS

FIG. 1 is a block diagram showing a pattern generating apparatus according to a first embodiment of the invention.

FIG. 2 is a flowchart showing a sequence of generating a pattern of a bypass capacitor according to the first embodiment of the invention.

FIG. 3 is a cross-sectional view showing a wiring line according to the first embodiment of the invention.

FIG. 4 is a view showing a process of manufacturing the wiring line according to the first embodiment of the invention.

FIG. 5 is an explanatory view showing a process of arranging a capacitor according to the first embodiment of the invention.

FIG. 6 is an explanatory view showing a process of arranging the capacitor according to the first embodiment of the invention.

FIG. 7 is an explanatory view showing a process of arranging the capacitor according to the first embodiment of the invention.

FIG. 8 is an explanatory view showing a process of arranging the capacitor according to the first embodiment of the invention.

FIG. 9 is an explanatory view showing a second embodiment of the invention.

FIG. 10 is an explanatory view showing a third embodiment of the invention.

FIG. 11(a) and FIG. 11(b) are explanatory views showing a fourth embodiment of the invention.

FIG. 12 is an explanatory view showing a fifth embodiment of the invention.

FIG. 13 is an explanatory view showing the relationships between a capacitor and a pattern shape in the fifth embodiment of the invention.

FIG. 14(a) and FIG. 14(b) are explanatory views showing the relationships between the capacitor and the pattern shape in the fifth embodiment of the invention.

FIG. 15 is an explanatory view showing the relationships between the capacitor and the pattern shape in the fifth embodiment of the invention.

FIG. 16 is an explanatory view showing a sixth embodiment of the invention.

FIG. 17 is a view showing a manufacturing process according to a seventh embodiment of the invention.

### DESCRIPTION OF THE PREFERRED EMBODIMENTS

Hereinafter, embodiments of the invention will be described in detail with reference to the accompanying drawings.

### First Embodiment

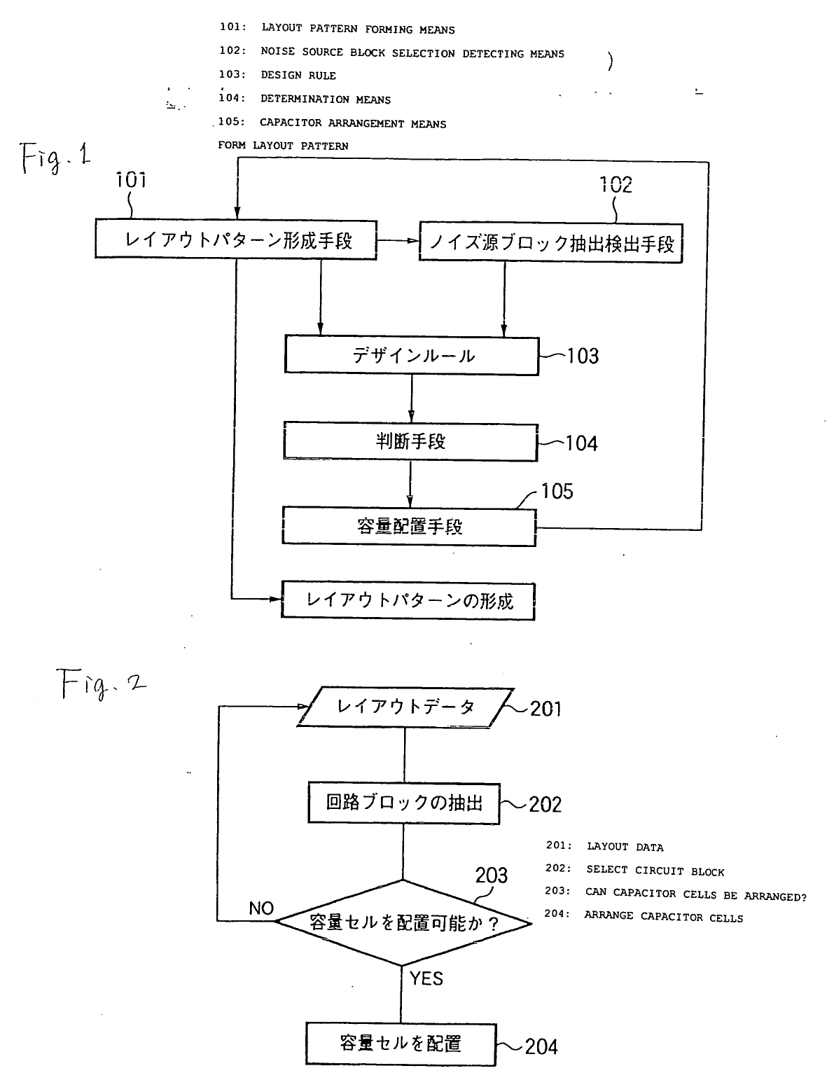

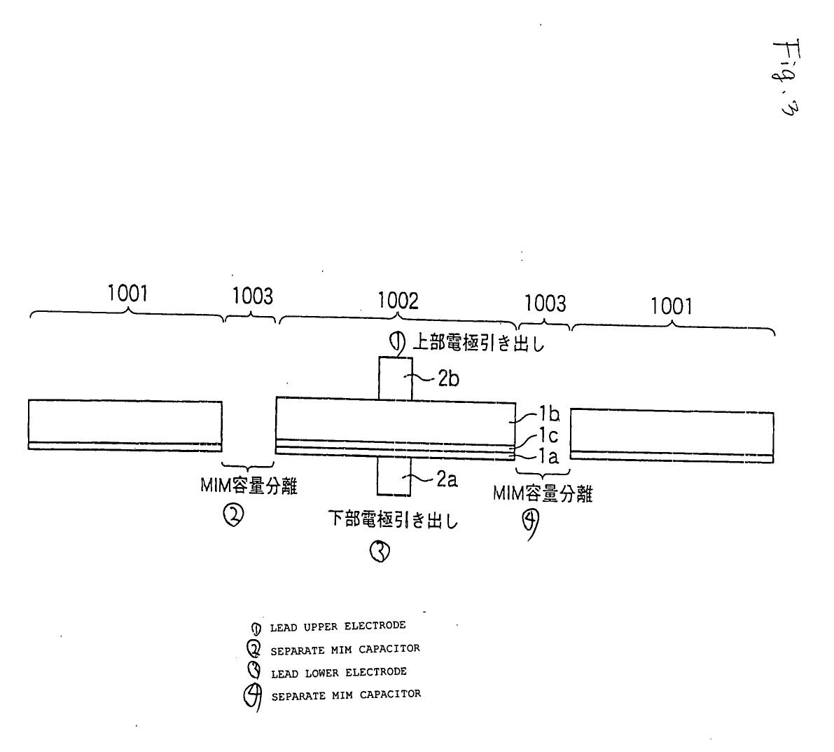

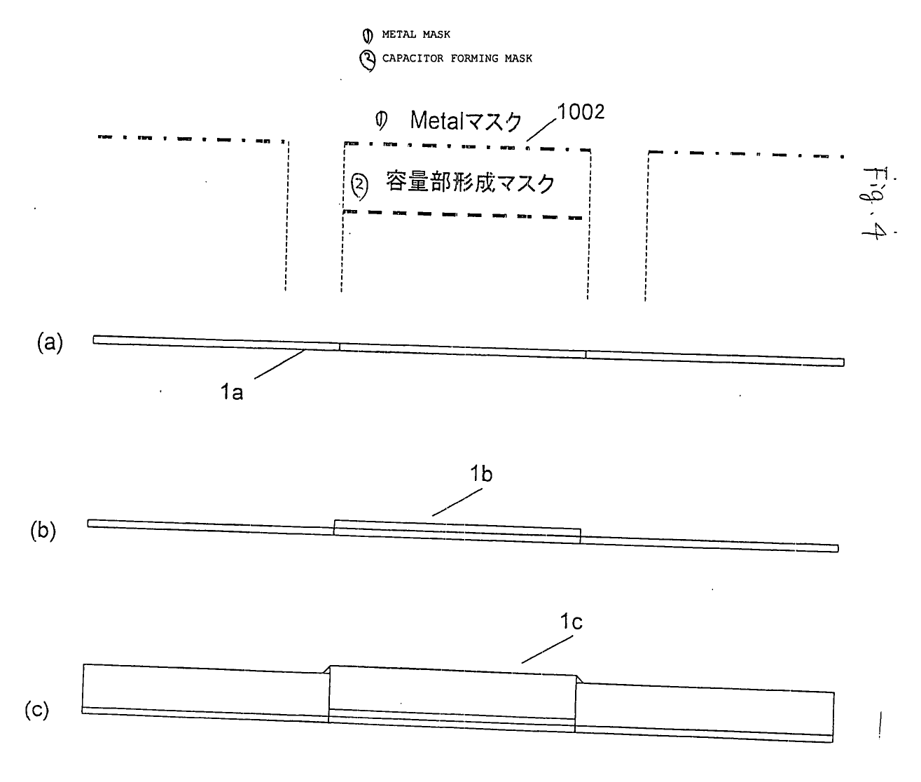

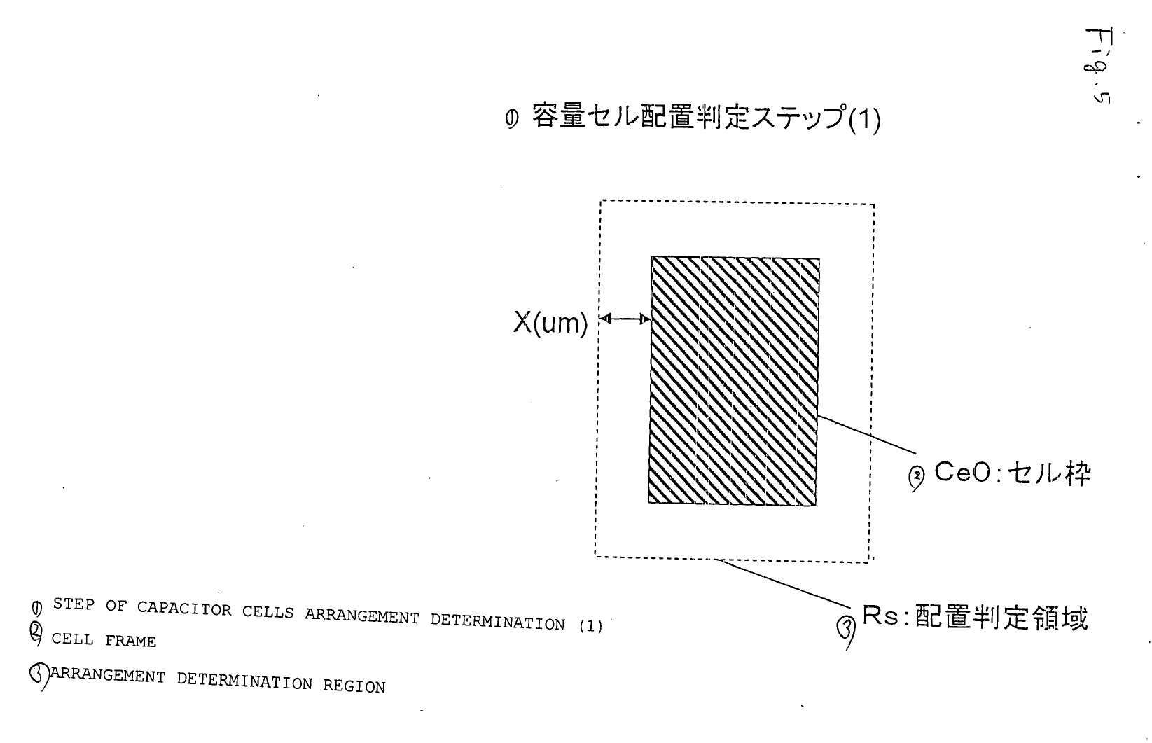

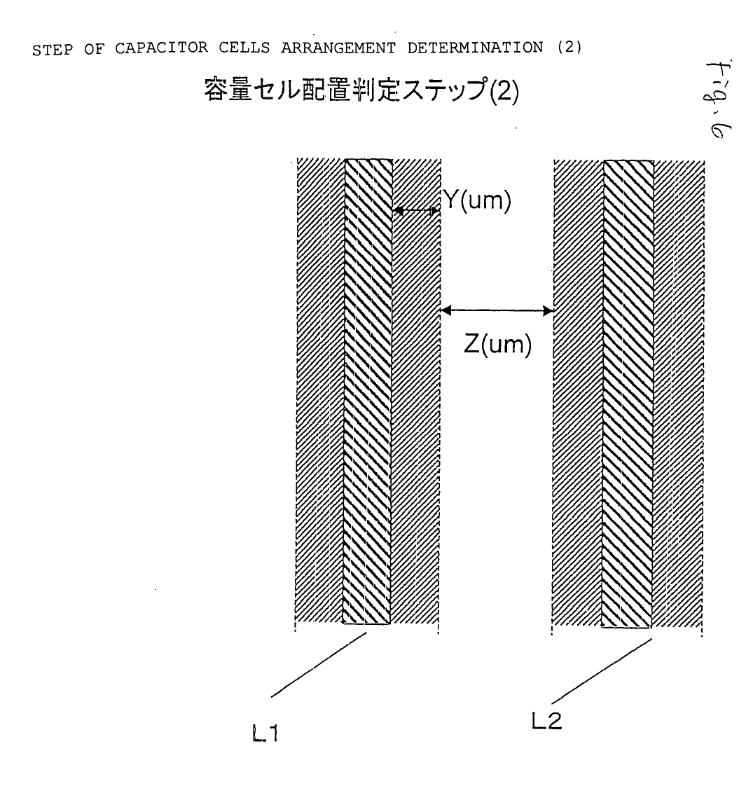

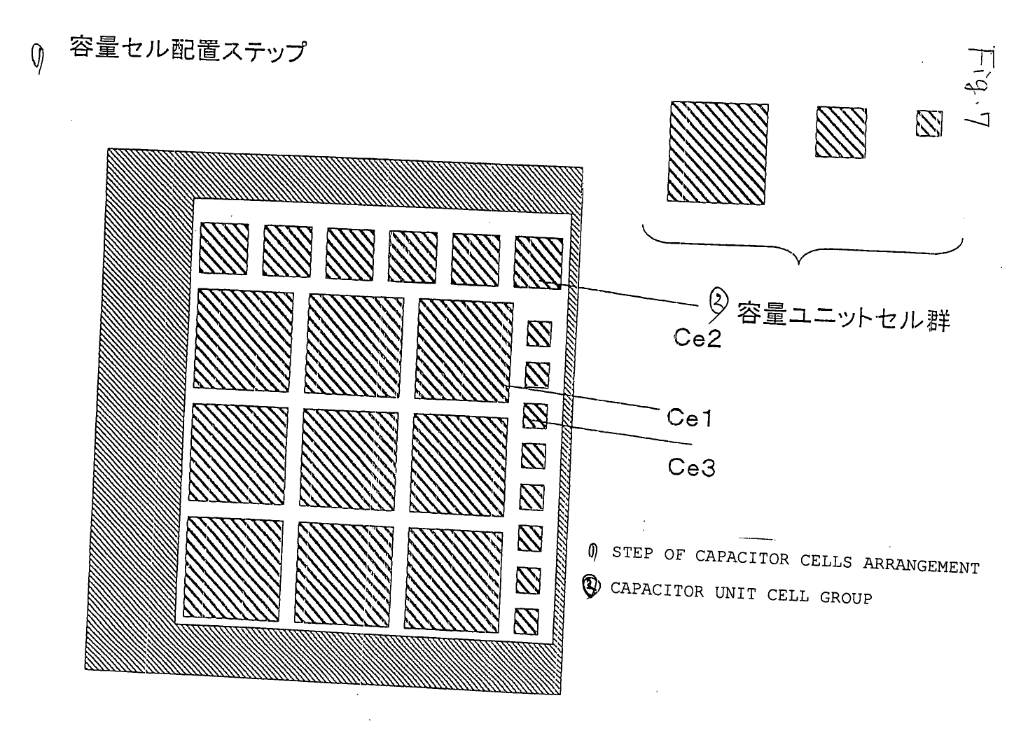

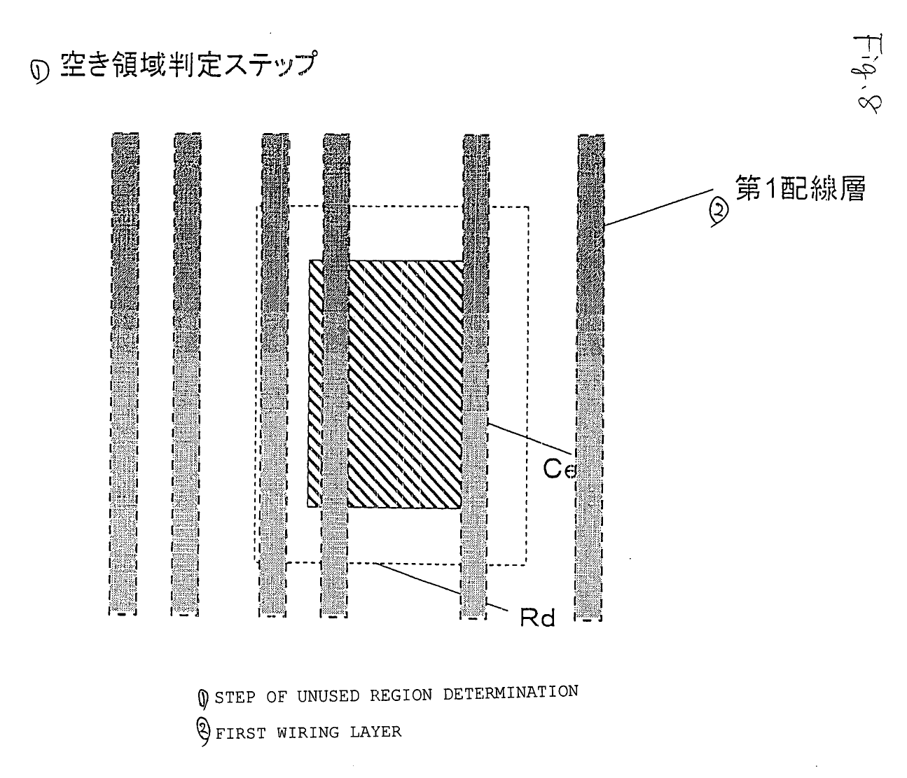

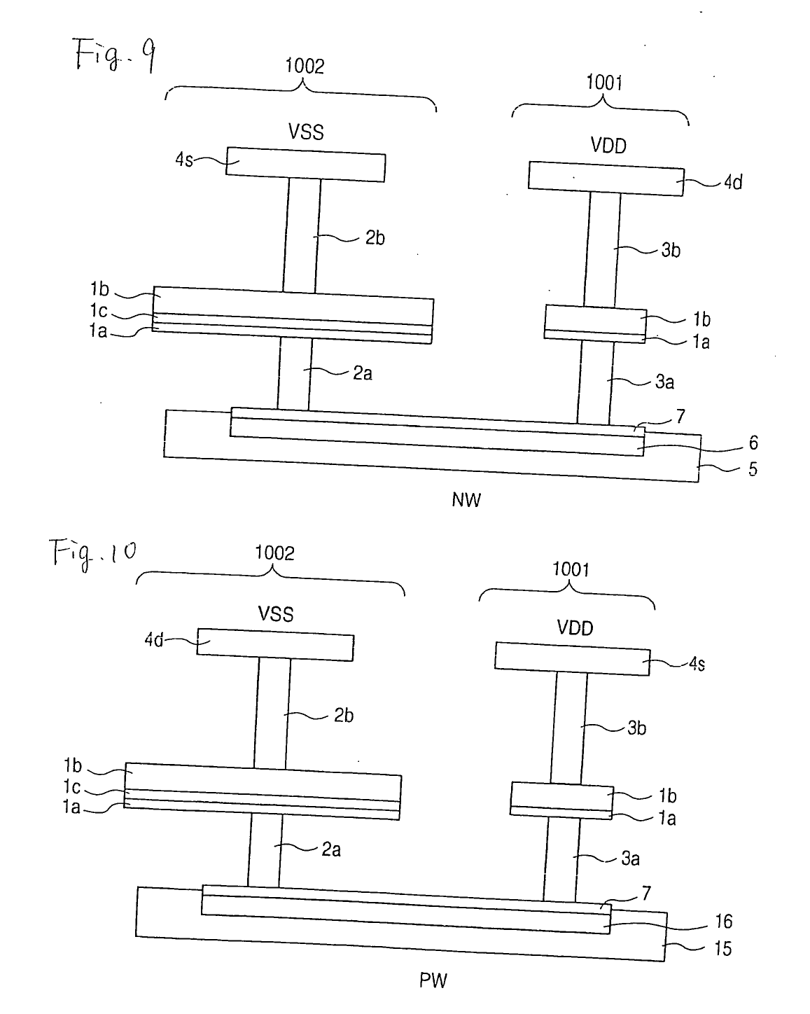

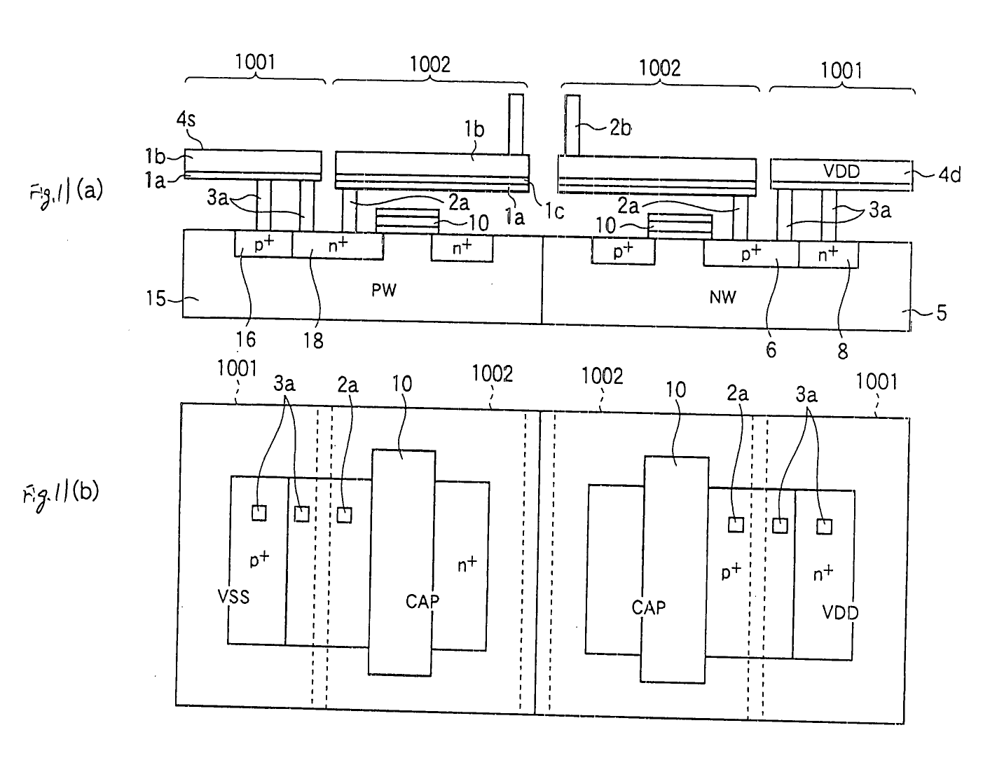

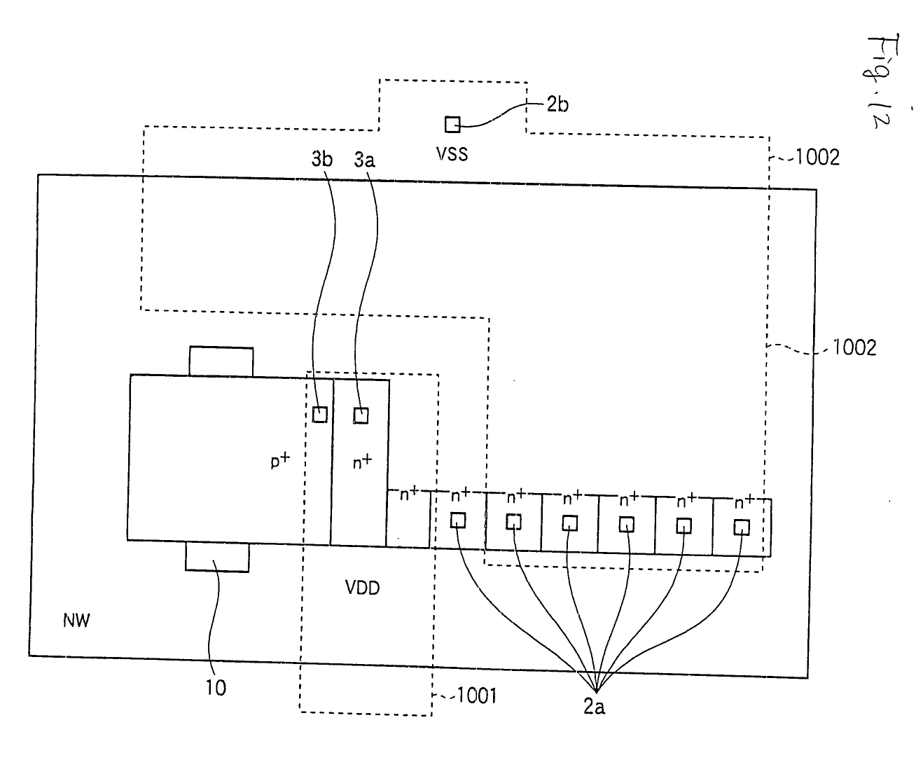

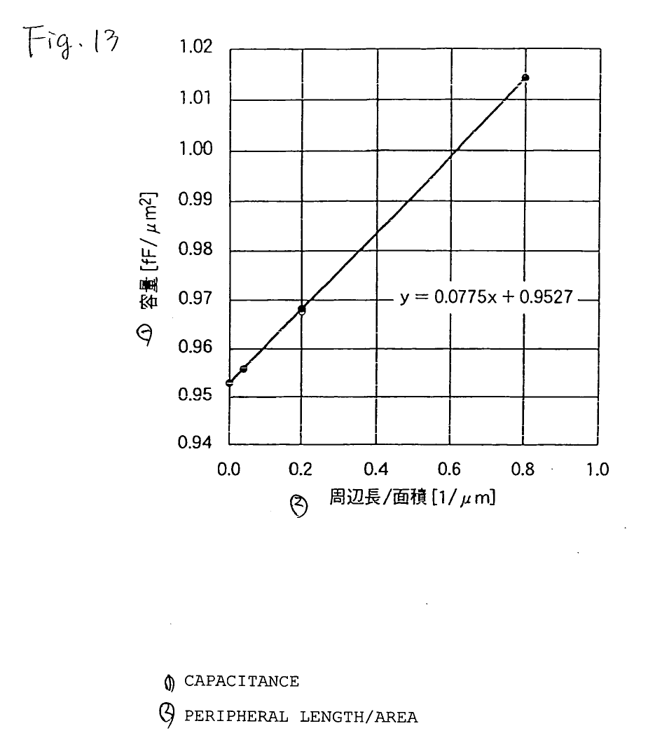

FIG. 1 is a block diagram showing a pattern generating apparatus according to a first embodiment of the invention, and FIG. 2 is a flowchart showing a method of generating a pattern.

According to the first embodiment, a decoupling capacitor C_{D} is formed on a circuit block N which becomes a noise source. As shown in FIG. 3, a region is formed in which a capacitor insulating film 1c is interposed between first and second conductor layers 1a and 1b constituting one wiring layer 1 located on the circuit block becoming the noise source in a layout pattern. In addition, the first and second conductor layers 1a and 1b are connected to a power supply line 2a and a grounding line 2b to form a capacitive element, and the decoupling capacitor C_{D} composed of the capacitive element is formed on the wiring layer.

As shown in FIG. 1, the pattern generating apparatus includes a layout pattern forming means 101 that designs and arranges a layout pattern of a semiconductor chip, a noise block selection means 102 that selects a circuit block becoming a noise source from a layout pattern generated by the layout pattern forming means 101, a design rule selection means 103 that selects a design rule according to the layout, a determination means 104 that determines whether capacitor cells can be arranged on the circuit block, and a capacitor arrangement means 105 that arranges the capacitor cells on an arrangement region using, as the arrangement region, a region determined by the determination means that the capacitor cells can be arranged. In addition, the decoupling capacitor is arranged on the wiring layer and thus layout pattern data to which the capacitor is added again is output from the layout pattern forming means 101.

That is, as shown in FIG. 2, in the pattern generating apparatus, a layout pattern is designed according to layout data 201 of the semiconductor chip to be arranged. Next, a circuit block in which a noise is easily generated, that is, a circuit block which is easy to be a noise source is selected from the layout pattern (step 202). Next, it is determined, on the basis of a technology obtained by the design rule, whether the capacitor cells can be arranged on the circuit block in which a noise is easy to be generated (step 203). Next, a capacitor is arranged on an arrangement region using, as the arrangement region, a region determined that the capacitor cells can be arranged (step 204).

In the step 203, determinations of two steps are actually performed. First, as shown in FIG. 5, it is determined whether a wiring layout exists in an arrangement determination region Rd on the circuit block determined to be the noise source. Then, when it is determined whether the wiring pattern does not exist in the arrangement determination region Rd, it is determined that a capacitor cell having a cell frame CeO can be arranged (step 1).

Next, in a case in which it is determined that the wiring pattern exists in the arrangement determination region Rd, when sizes of wiring patterns L1 and L2 are increased by a predetermined wiring margin Y (μm), it is determined whether a gap Z (μm) between the wiring patterns L1 and L2 is larger than a minimum value of the size of the capacitor cell formed by the design rule (step 2).

When it is determined that the capacitor cells can be arranged in the step 1, a capacitor cell Ce is arranged in the step 204 in which the capacitor cells are arranged, as shown in FIG. 7. In the step 204 in which the capacitor cells are arranged, the capacitor cells are arranged on a region Rd determined that a capacitor unit cell can be arranged. Here, in order not that the capacitor unit cell does not extrude from the region in which the capacitor cells can be arranged, unit cells are sequentially arranged in order of a unit cell Ce1 having a large size and a next unit cell Ce2 having a small size.

In addition, when it is determined that the capacitor cells can be arranged in the step 1, the determination at the step 2 is performed. As shown in FIG. 8, for example, when a wiring pattern L11 of the first wiring layer exists in the arrangement determination region Rd, it is determined whether the capacitor cells are formed on a second wiring layer located over the first wiring layer. In this way, the wiring layers, on which the capacitor cells can be arranged, are sequentially searched in an upward direction.

As such, the circuit block in which the noise is easy to be generated is selected and thus the bypass capacitor is arranged on the circuit block. Accordingly, it is possible to perform the pattern layout efficiently and easily such that the automatic formation is facilitated.

The technology obtained by the design rule means that sizes of the elements such as the cell, the bypass capacitor and the wiring line are defined by design rules of the respective processes such as a diffusion process, a sputtering process and an etching process.

As shown in FIG. 3, in this example, the capacitor insulating film 1c is interposed between the first and second conductor layers 1a and 1b constituting one wiring layer 1 in a region where the decoupling capacitor is to be formed, thereby forming the capacitive element.

Here, a wiring layer 1 has a polyside structure composed of a polycrystalline silicon layer 1a having a thickness of about 180 nm and a tungsten layer 1b having a thickness of about 300 nm. When the wiring layer 1 is formed, a silicon nitride film 1c having a thickness of 64 nm, serving as a capacitor insulating film, is interposed between the polycrystalline silicon layer 1a and the tungsten layer 1b in the wiring layer.

That is, in a wiring region 1001, the polyside structure composed of the polycrystalline silicon layer 1a and the tungsten layer 1b formed on the polycrystalline silicon layer 1a is formed. In a capacitor forming region 1002, the silicon nitride film 1c is interposed between the polycrystalline silicon layer 1a and the tungsten layer 1b formed on the polycrystalline silicon layer 1a, thereby forming the decoupling capacitor C_{D}.

According to the structure, the capacitor forming region 1002 is separated from the wiring region 1001 with the capacitor separating region 1003 interposed therebetween. In addition, the polycrystalline silicon layer 1a connected to a low contact 2a is connected to the same potential as that of the wiring layer, and the tungsten layer 1b is connected to the grounding potential or power supply potential through an upper contact 2b. Thereby, the decoupling capacitor can be additionally provided without increasing the number of processes.

As shown in FIGS. 1 and 2, a semiconductor integrated circuit device is manufactured according to the formed layout pattern. As shown in FIGS. 4A to 4C, when the semiconductor integrated circuit device is manufactured, the additional installation of the decoupling capacitor is performed simultaneously with the forming of the wiring layer.

First, as shown in FIG. 4A, when the wiring layer is formed, the polycrystalline silicon layer 1a is formed by a CVD method.

Further, as shown in FIG. 4B, a silicon nitride film 1c, serving as the capacitor insulating film, is formed by a sputtering method. Then, the silicon nitride film 1c remains only on the capacitor forming region 1002 through the photography and etching technologies using a mask corresponding to the capacitor forming region 1002.

Subsequently, as shown in FIG. 4C, the tungsten layer 1b is formed on the silicon nitride film 1c through the CVD method.

Next, in order to form the wiring pattern, a resist pattern is formed by a typical photolithography process, and the etching process is performed using the resist pattern as a mask. As a result, as shown in FIG. 3, the wiring line region 1001 and the capacitor forming region 1002 are formed. In the wiring region 1001, the polyside structure composed of the polycrystalline silicon layer 1a and the tungsten layer 1b formed on the polycrystalline silicon layer 1a is formed. In the capacitor forming region 1002, the decoupling capacitor is formed, in which the silicon nitride film is interposed between the polycrystalline silicon layer 1a and the tungsten layer 1b formed on the polycrystalline silicon layer 1a.

Through this structure, the wiring layer is formed in a structure of two layers and a dielectric layer is interposed in a region in which the capacitive element is formed. As a result, the capacitor can be additionally provided with ease. That is, the entire region of the first and second conductor layers, which are opposite to each other, serves as the capacitor to effectively use the area. Also, since a potential at the substrate side can be drawn out by the diffusion region, the size of a resistor for extracting the potential is small, and thus the essential elements can be integrally formed over the large area. In addition, since the first and second conductor layers can be formed through the same process as that of the wiring layer, the manufacturing process can be easily performed.

### Second Embodiment

The second embodiment illustrates the contact structure to supply the potential to the capacitor forming region described in the first embodiment. FIGS. 9 and 10 show an example of the contact structure. In addition, FIGS. 9 and 10 shows an example of a case in which the decoupling capacitor is provided in any region of a wiring line 4s connected to a ground potential Vss or a wiring line 4d connected to the power supply potential V_{DD}. FIG. 9 shows an example in which the capacitor forming region 1002 is arranged on the region of the wiring line 4S connected to the grounding potential Vss and FIG. 10 shows an example in which the capacitor forming region 1002 is arranged on the region of the wiring line 4d connected to the power supply potential V_{DD}. As such, similarly to the first embodiment, the capacitor forming region 1002 and the wiring region 1001 are formed. According to this example, in the substrate, a potential is supplied to a polycrystalline silicon layer 1a serving as a lower side electrode of the capacitor forming region 1002 through the silicide layer 7 formed on the surfaces of highly concentrated diffusion regions 6 and 16 formed on the surfaces of wells 5 and 15.

In addition, according to the second embodiment, the same constituent elements as those of the first embodiment are denoted by the same reference numerals.

As shown in FIG. 9, for example, since the silicon nitride film 1c is interposed between the polycrystalline silicon layer 1a and the tungsten layer 1b to form the decoupling capacitor, the tungsten layer 1b serving as the upper side electrode of the capacitor forming region 102 is connected to the wiring line 4s which is connected to the grounding potential Vss through the first contact 2b.

The polycrystalline silicon layer 1a which becomes one lower side electrode contacts with the silicide layer 7 provided on the surface of the silicon substrate through the first substrate contact 2a and is connected to a second substrate contact 3a through the silicide layer 7. In addition, the second substrate contact 3a is connected to the polycrystalline silicon layer 1a and the tungsten layer 1b of the wiring region 1001. In addition, the second substrate contact 3a is connected to a power supply wiring line 4d through an electrode contact 3b provided to contact with a wiring region 1001.

In the example shown in FIG. 10, since the silicon nitride film 1c is interposed between the polycrystalline silicon layer 1a and the tungsten layer 1b to form the decoupling capacitor, the tungsten layer 1b serving as the upper side electrode of the capacitor forming region 1002 is connected to the wiring line 4d which is connected to the power supply potential V_{DD} through the first contact 2b.

The polycrystalline silicon layer 1a serving as one lower side electrode contacts with the silicide layer 7 provided on the surface of the silicon substrate through a first substrate contact 2a and is connected to a second substrate contact 3a through the silicide layer 7. Also, the second substrate contact 3a is connected to the polycrystalline silicon layer 1a and the tungsten layer 1b of the wiring region 1001. In addition, the second substrate contact 3a is connected to a grounding wiring line 4s through an electrode contact 3b provided so as to contact with a wiring region 1001.

In this way, it is possible to form the decoupling capacitor on the circuit block, in which a large amount of noise is generated, without increasing an occupation area.

According to the second embodiment, by automatically arranging the bypass capacitor under the power supply wiring line 1, it is possible to provide a capacitor by which power supply noise is reduced without increasing the area of the chip. Also, the diffusion region 15 to form the bypass capacitor under the power wiring line 5 and the diffusion region 16 to form the substrate contact under the grounding wiring line are connected to each other, and thus the power supply wiring line and the bypass capacitor can be connected to each other with a resistance lower than that of the substrate having a high resistance. In addition, the grounding wiring line 5 and the bypass capacitor can be connected to each other with the resistance lower than that of the substrate.

Further, the metallic silicide layer 7 can be formed with the same process as that of a silicide layer located at another region before the gate insulating film is formed. Also, when the polysilicon layer constituting the gate electrode of the bypass capacitor is subjected to the silicification process, the gate insulating film is patterned simultaneously with patterning of the polysilicon, and then a metallic layer is formed and is subjected to the silicification process. After that, by selectively etching and removing a part subjected to the silicification process, that is, a metallic layer provided at the side surface of the gate insulating film, it is possible to remove the part located under the gate electrode and to form the silicide layer on the surface of the substrate. In this way, the current extraction can be performed without a PN junction, thereby obtaining a superior bypass capacitor.

### Third Embodiment

The third embodiment illustrates a modification example of the decoupling capacitor illustrated in the second embodiment. That is, the third embodiment illustrates a modification example of the contact structure so as to supply the potential to the capacitor forming region. According to the third embodiment, a decoupling capacitor is formed on a circuit block including an MOSFET. The MOSFET includes a gate electrode 10 and a source/drain composed of an n⁺ diffusion region 18 and a p⁺ diffusion region 6.

FIGS. 11A and 11B are a cross-sectional view and a top view of the contact structure. In the third embodiment, a wiring line of the capacitor forming region 1002 is composed of a wiring line 4d connected to a power supply potential V_{DD} and a wiring line 4s connected to a grounding potential Vss. In addition, the wiring line 4s connected to the grounding potential Vss and the wiring line 4d connected to the power supply potential V_{DD} are directly connected to substrate contacts 3a formed on the p⁺ diffusion region 16 and the n⁺ diffusion region 18 so as to fix the potentials of a P well and an N well. In addition, these wiring lines 4s and 4d are connected to the source/drain composed of the n⁺ diffusion region 18 and the p⁺ diffusion region 6 through the second substrate contact 3a and are connected to the first electrode 1a of the capacitor forming region.

As apparent from the top view shown in FIG. 11B, the entire surface of the substrate where the circuit block including the MOSFET is formed can be covered with the wiring lines, and therefore a decoupling capacitor having a large capacitance can be formed.

According to the structure, the decoupling capacitor can be formed more adjacent to the circuit block serving as the noise generating source, the number of depositing wiring layers can be reduced, and the surface can be planarized.

### Fourth Embodiment

According to a fourth embodiment, as shown in FIG. 12, sizes of diffusion regions are increased to fix a substrate potential and a decoupling capacitor is formed on the diffusion regions. In the fourth embodiment, second substrate contacts 3a are arranged in an array, a wiring layer is divided into two layers, and a capacitor forming region where a capacitor insulting film is formed between the two layers is provided.

FIG. 12 shows a modification example of the coupling capacitor described in the third embodiment. In FIG. 12, similarly to FIG. 11A, a capacitor forming region 1002 is formed at the outside of a wiring region 1001 located at a right end, a substrate contact 3a is connected to a wiring line 4d connected to a power supply potential V_{DD} through a first substrate contact 2a, and a tungsten layer 1b serving as an upper layer side electrode is connected to a wiring line 4S connected to an upper layer side grounding potential Vss through the first contact 2b. As a result, the capacitor forming region 1002 serves as the decoupling capacitor.

In addition, the same constituent elements as those of the first to third embodiments are denoted by the same reference numerals and the description thereof is omitted.

### Fifth Embodiment

According to a fifth embodiment, a decoupling capacitor is formed on a circuit block serving as a noise source to prevent the noise from being transmitted. It is preferable that a capacitor having a large capacitance be formed without increasing an occupation area. According to the present embodiment, the relationships between the capacitor and the occupation area are measured and the shape thereof is optimized.

Firstly, similarly to the first embodiment, an evaluation pattern having an area of 0.01 to 1 mm² and a peripheral length of 0.04 to 8 mm is formed. Here, as the capacitor insulating film, a silicon nitride film, having a thickness of 64 nm, formed by a plasma CVD method is used.

It will be apparent from the measured result that a total capacitance C be a sum of a capacitance Cs of an area component and a capacitance C1 of a fringe portion.
C=Cs*S+C1*L
Cs=0.9527 fF/μm²
C1=0.0775 fF/μm
C: capacitor
S: area
L: peripheral length

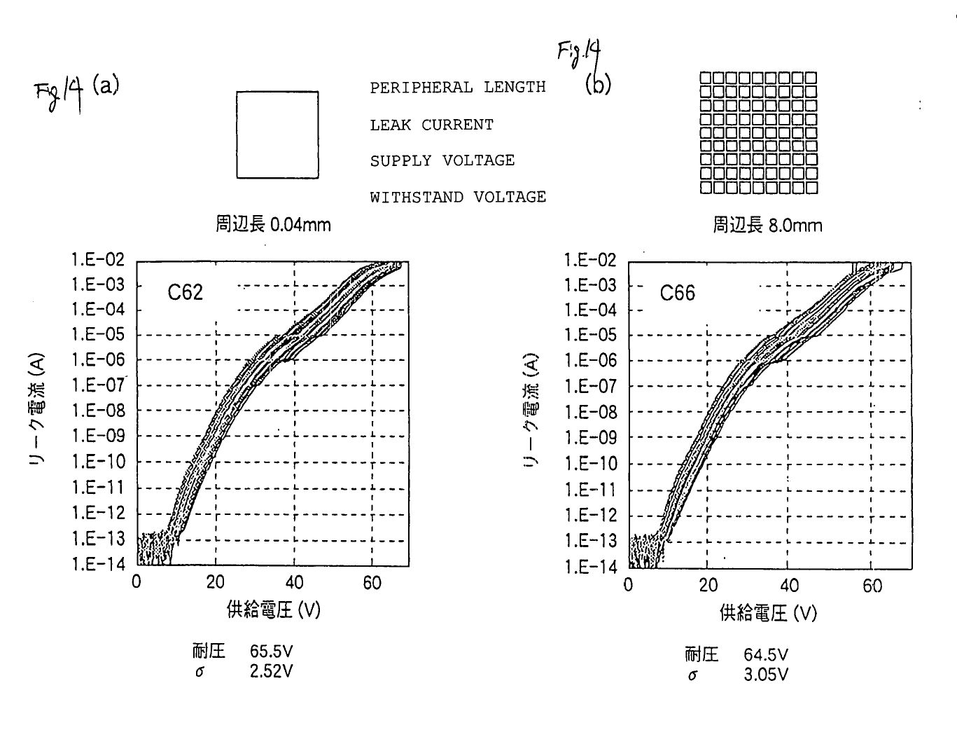

FIG. 13 shows the relationships between the capacitance and the peripheral length/area. Here, a horizontal axis indicates the peripheral length/area and a vertical axis indicates the capacitance. It can be seen from FIG. 13 that as the peripheral length increases, the capacitance increases.

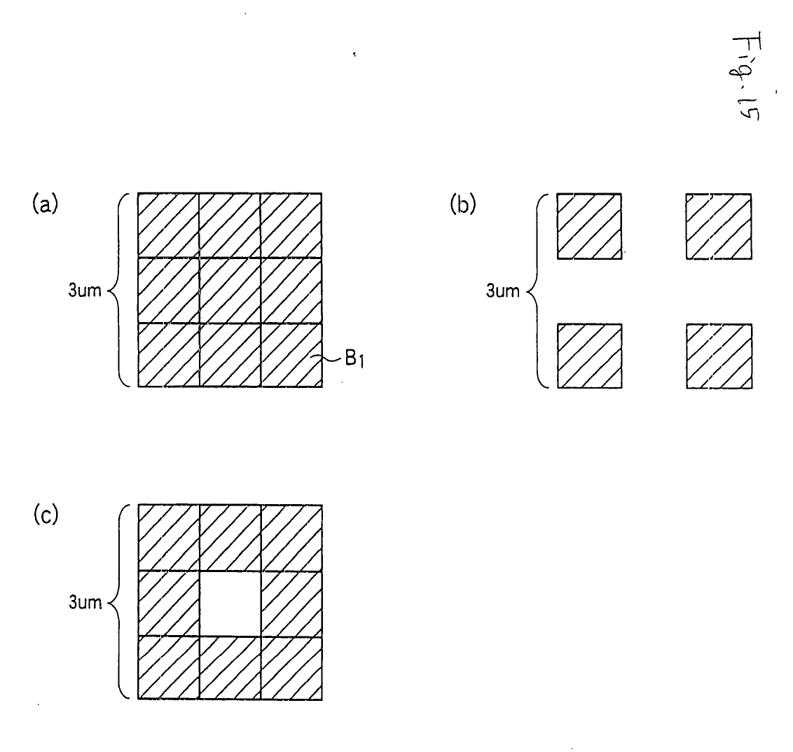

Further, a withstand voltage and a leak current are measured when the area is fixedly set to have 0.01 mm² and the peripheral length is in a range of 0.04 to 8.0 mm. The measured results are shown in FIGS. 14A and 14B. Here, since the withstand voltage and deviation thereof are a little large, but the capacitance can be large, and accordingly it is preferable to have a matrix shape, as shown in FIG. 14B.

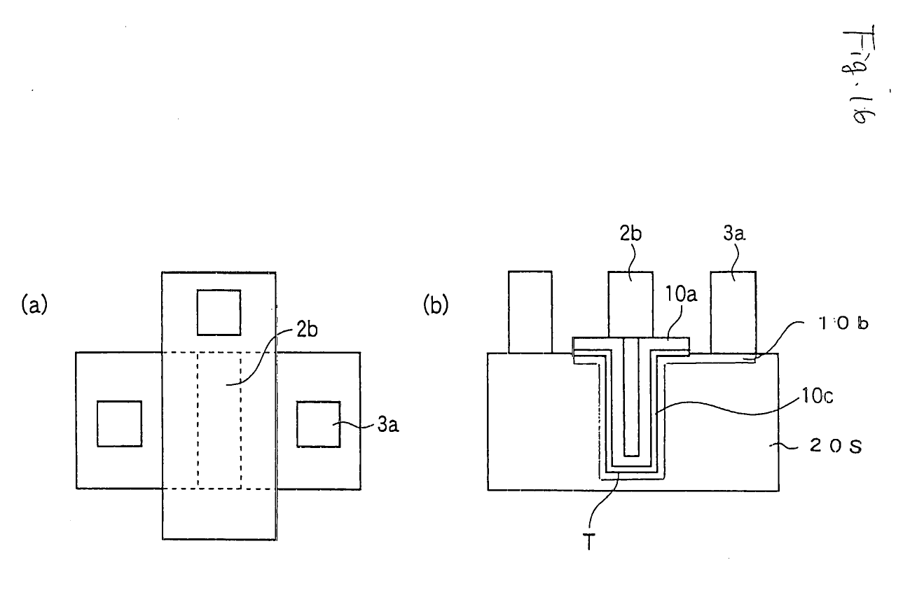

FIGS. 15A to 15C shows the change of a capacitance value according to a shape when an occupation area is constant. Here, the overall block is divided into nine small blocks B1. All the blocks are integrally formed to form C1, only the small blocks B1 located at the peripheral portion constitute the capacitor block to form C2, and the small block B1 only located at the central portion is removed to form C3. At this time, the capacitance values are respectively 9.5043 (fF), 5.5018 (fF) and 8.8616 (fF).

By using the above-mentioned results, the small blocks may be integrally formed if necessary, the small blocks may be divided in an array, and the pattern shape of the capacitor pattern may be suitably selected.

### Six Embodiment

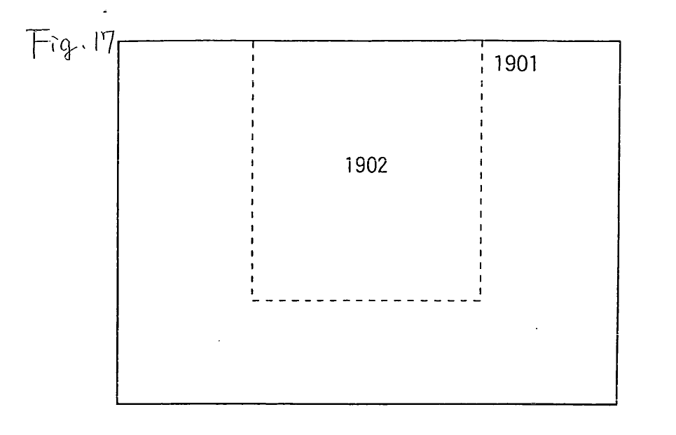

In the first to fifth embodiments, the examples in which the bypass capacitor is formed on the substrate surface with the interlayer insulating film interposed therebetween are described. However, according to the sixth embodiment, as shown in FIG. 16, a trench T is formed on an interlayer insulating film 20S formed on a surface of the substrate, a polycrystalline silicon layer 10b serving as a first wiring layer is provided in the trench T, the surface of the polycrystalline silicon layer 10b is subjected to an oxidization process, an oxidization silicon film 10c is formed on the surface of the polycrystalline silicon layer 10b, and a tungsten layer 10a serving as a second wiring layer is formed on the oxidization silicon film 10c. Here, the surface of the first wiring layer is subjected to the oxidization process and the capacitor insulating film 10c is formed on the surface of the first wiring layer. In addition, when the tungsten layer serving as the second wiring layer is formed, a second conductor layer 15a serving as the upper layer side electrode is formed, so that a bypass capacitor is formed. The second wiring layer 10a is connected to a wiring line 4s connected to a grounding potential Vss through a contact 2b. On the other hand, the polycrystalline silicon layer serving as the first wiring layer 10b is connected to a wiring line (not shown) connected to a power supply potential V_{DD} through a substrate contact 3a.

As such, only by forming the trench in the interlayer insulating film formed on the surface of the substrate, it is possible to form a decoupling capacitor having a large capacitance without increasing the number of processes by forming the wiring line in the middle of the process of manufacturing the MOSFET.

Further, after forming the trench in the interlayer film, the first wiring layer is provided at an inner wall of the trench, the surface of the first wiring layer is subjected to the oxidization process and the second wiring layer 10a is formed on the first wiring layer. However, the capacitor insulting film may be separately formed.

Actually, a region, in which the decoupling capacitor can be arranged, is selected when the pattern is generated. Also, when a connecting diffusion layer is arranged, a part where the substrate contact region and the connecting diffusion layer overlap is separated to be connected to the wiring line. The processes can be automatically performed through a graphical logic operation and a resizing process.

Furthermore, according to the sixth embodiment, the trench T is formed. However, it is possible to form a bypass capacitor having a large capacitance with the second conductor layer formed through the capacitor insulting film, even though the first conductor layer having uneven portions formed on the surface is used without necessarily forming the trench.

In this way, it is possible to increase the capacitance only by changing the wiring pattern. In addition, by not only forming the uneven portions but also suitably adjusting a shape of the capacitor, for example, to be a fin shape, it is possible to achieve a capacitor having a large capacitance.

In addition, the plurality of bypass capacitors may be arranged in an array. Thereby, it is possible to form a capacitance having a large capacitance more efficiently under the power supply wiring line.

In addition, it is preferable that each of the bypass capacitors have a different capacitor insulating film and have a different capacitance per unit area in the chip. Here, the situation of the region is determined from the design rule in consideration of specification, and the bypass capacitor having the different characteristics is provided for each region. Generally, it is necessary that a high withstand voltage exist at an outer circumference of the chip located near the power supply in order to prevent the surge. On the contrary, it is not necessary that a high withstand voltage exist at the inside of the chip. For this reason, the thickness of the gate insulating film is large in the vicinity of the outer circumference of the chip and the thickness of the gate insulating film is small at the inside of the chip. In addition, there is a case in which the gate insulating film having the multi-layered structure is provided in the vicinity of the outer circumference of the chip.

In addition, frequency characteristics are important in the vicinities of the functional elements. That is, it is necessary that the bypass capacitor having a large capacitance be provided for use in a high frequency, while the bypass capacitor having a small capacitance be provided for use in a low frequency.

Further, the distance from the chip frame toward an inner direction may be divided into a peripheral portion and the inner portion by the logic operation and resizing process with the process information set an original distance, and thus the bypass capacitors having different specifications may be arranged. The situation of the region is determined from the design rule in consideration of the specification, and the bypass capacitor having the different characteristics is provided for each region. As a result, it is possible to provide a semiconductor integrated circuit device with excellent characteristics and high reliability.

Furthermore, when the bypass capacitor is formed with a minimum graphic size of the wiring pattern rule in manufacturing the semiconductor, it is possible to design the pattern automatically.

### Seventh Embodiment

As shown in FIG. 17, in a semiconductor integrated circuit device, a bypass capacitor constituting a decoupling capacitor, inserted according to a circuit block to be connected, is divided into a bypass capacitor 1901 for small capacitor region and a bypass capacitor 1902 for large capacitor region.

Here, the situation of the region is determined from the design rule in consideration of specification, and the bypass capacitor having the different characteristics is provided for each region. Generally, it is necessary that a high withstand voltage exist at an outer circumference of the chip located near the power supply in order to prevent the surge. On the contrary, it is not necessary that a high withstand voltage exist at the inside of the chip. For this reason, a thickness of the gate insulating film is large in the vicinity of the outer circumference of the chip and the thickness of the gate insulating film is small at the inside of the chip.

In addition, there is a case in which the gate insulating film having the multi-layered structure is provided only in the vicinity of the outer circumference of the chip.

Further, the frequency characteristics are important in the vicinities of the functional elements. That is, it is necessary that the bypass capacitor having a large capacitance be provided for use in a high frequency, while the bypass capacitor having a small capacitance be provided for use in a low frequency. Therefore, the bypass capacitor is suitably selected according to a frequency band to be used.

According to the invention, it is possible to provide a semiconductor integrated circuit device with low noise and high reliability. Therefore, the invention can be effectively used for an integrated circuit in which an analog circuit and a digital circuit are mixed.

1. A semiconductor integrated circuit device having at least one circuit block comprising:
a bypass capacitor, having a first wiring layer and a second wiring layer formed on the first wiring layer with a capacitor insulating film interposed therebetween,
wherein the first and second wiring layers are formed to be respectively connected to two power supply lines which are connected to the circuit block and which have different potentials.

2. The semiconductor integrated circuit device according to claim 1,
wherein the bypass capacitor is arranged on the circuit block.

3. The semiconductor integrated circuit device according to claim 1 or 2,
wherein one of the first and second wiring layers of the bypass capacitor is connected to one of the power supply lines through a substrate contact which fixes a potential of a substrate.

4. The semiconductor integrated circuit device according to any one of claims 1 to 3,
wherein the bypass capacitor is formed with a capacitor insulating film interposed between the first and second wiring layers constituting one wiring layer, in other region of the semiconductor integrated circuit.

5. The semiconductor integrated circuit device according to any one of claims 1 to 4,
wherein one of the power supply lines is a grounding wiring line and the other is a power supply wiring line.

6. The semiconductor integrated circuit device according to any one of claims 1 to 5,
wherein the first wiring layer is connected to the grounding wiring line or power supply wiring line through a diffusion layer formed on a surface of the substrate.

7. The semiconductor integrated circuit device according to any one of claims 1 to 6,
wherein the bypass capacitor is formed under a power supply wiring line region.

8. The semiconductor integrated circuit device according to any one of claims 1 to 7,
wherein the first wiring layer contacts with a first diffusion region formed on the surface of the substrate, and
the first diffusion region is connected to a second diffusion region serving as a substrate contact which fixes the potential of the substrate.

9. The semiconductor integrated circuit device according to claim 8,
wherein the first diffusion region has the same conductive type as that of the second diffusion region constituting the substrate contact.

10. The semiconductor integrated circuit device according to claim 8,
wherein the first diffusion region has a different conductive type from that of the second diffusion region constituting the substrate contact, and
the first and second diffusion regions are connected to each other through a silicide layer formed on a surface of the second diffusion region.

11. The semiconductor integrated circuit device according to claim 1,
wherein the bypass capacitor is formed on the circuit block with the interlayer insulating film interposed therebetween and is composed of a first wiring layer having uneven portions formed on a surface thereof and a second wiring layer formed by interposing a capacitor insulating film therebetween.

12. The semiconductor integrated circuit device according to claim 1,
wherein the bypass capacitor is formed by sequentially laminating a first wiring layer formed along an inner wall of a trench formed on a surface of an insulating film and a capacitor insulating film and a second wiring layer formed on the first wiring layer.

13. The semiconductor integrated circuit device according to claim 11,
wherein the trench is formed along a trench separating region.

14. The semiconductor integrated circuit device according to any one of claims 1 to 13,
wherein the plurality of bypass capacitors are arranged in an array.

15. The semiconductor integrated circuit device according to claim 13,
wherein each of the bypass capacitors has a different capacitor insulating film and has a different capacitance per unit area in a chip.

16. The semiconductor integrated circuit device according to claim 1,
wherein the bypass capacitor is composed of a first wiring layer formed on the wiring region in a fin shape and a second wiring layer formed at a periphery of the first wiring layer with the capacitor insulating film interposed therebetween.

17. A method of generating a pattern of a semiconductor integrated circuit device, comprising the step of:
forming a layout pattern to design and arrange the layout pattern of a semiconductor chip;
selecting a circuit block, in which a noise is easy to be generated, from the layout pattern;
determining whether capacitor cells can be arranged on the circuit block; and
arranging a capacitor using, as an arrangement region, a region determined that the capacitor cells can be arranged on the circuit block in the determination step.

18. The method of generating a pattern of a semiconductor integrated circuit device according to claim 17,
wherein the determination step includes a step of detecting a wiring layer region, in which the capacitor cells are formed, in the circuit block of the layout pattern and of determining whether the capacitor cells can be arranged on the wiring layer region, and
the capacitor arrangement step includes a wiring line arrangement step of arranging a second wiring layer such that the capacitor insulating film is interposed in an upper layer or a lower layer of the wiring layer region determined that the capacitor cells can be arranged on the wiring layer region in the determination step and of wiring the second wiring layer such that the second wiring layer is connected to a different potential from that of the wiring layer region.

19. The method of generating a pattern of a semiconductor integrated circuit device according to claim 18,
wherein the wiring line arrangement step includes a step of connecting the second wiring layer to a power supply wiring line or a grounding wiring line.

20. The method of generating a pattern of a semiconductor integrated circuit device according to claim 17,
wherein the determination step includes the steps of:
detecting a region, in which capacitor cells are formed, in the circuit block among wiring lines of the layout pattern;
arranging the capacitor cells in a region determined that the capacitor cells can be formed in the determination step; and
arranging wiring lines such that one conductor of each of the capacitor cells is connected to a first potential and a substrate is connected to a second potential.

21. A pattern generating apparatus for a semiconductor integrated circuit device comprising:
a layout pattern forming means for designing and arranging a layout pattern of a semiconductor chip;
a selection means for selecting a circuit block, in which a noise is easy to be generated, from the layout pattern;
a determination means for determining whether capacitor cells can be arranged on the circuit block; and
a capacitor arrangement means for arranging a capacitor using, as an arrangement region, a region determined that the capacitor cells can be arranged on the circuit block in the determination means.

22. A method of manufacturing a semiconductor integrated circuit device using the pattern for the semiconductor integrated circuit device generated by the method of generating the pattern of the semiconductor integrated circuit device according to any one of claims 17 to 20.
